(19) United States
(12) Patent Application Publication
(10) Pub. No.: US 2026/0019058 A1
(43) Pub. Date: Jan. 15, 2026

(54) FILTER DEVICE AND METHOD FOR CONTROLLING A FILTER DEVICE

(71) Applicant: Murata Manufacturing Co., Ltd., Nagaokakyo-shi (JP)

(72) Inventor: Naoki MIZOGUCHI, Nagaokakyo-shi (JP)

(73) Assignee: Murata Manufacturing Co., Ltd., Nagaokakyo-shi (JP)

(21) Appl. No.: 19/332,135

(22) Filed: Sep. 18, 2025

Related U.S. Application Data
(63) Continuation of application No. PCT/JP2024/010093, filed on Mar. 14, 2024.

(30) Foreign Application Priority Data
Mar. 20, 2023 (JP) 2023-044202

(51) Int. Cl. H03H 7/01; H03H 1/00

(52) U.S. Cl. CPC H03H 7/0161; H03H 1/00; H03H 7/0115; H03H 2001/0085

(57) ABSTRACT

A filter device includes an input terminal, an output terminal, and a resonator connected to the input terminal and the output terminal. The resonator includes a first terminal connected to the input terminal, a second terminal connected to the output terminal, first and second inductors, and first to third capacitors. A first end of the first inductor is connected to the first terminal. The second inductor has a first end connected to the second terminal and a second end connected to a second end of the second inductor. A first end of the first capacitor is connected to the first terminal. The second capacitor has a first end connected to the second terminal and a second end connected to the second end of the capacitor. The third capacitor is connected between a second end of the first inductor and a second end of the first capacitor.

### CROSS-REFERENCE TO RELATED APPLICATIONS

The present application is a continuation of International Application No. PCT/JP2024/010093, filed Mar. 14, 2024, which claims priority to Japanese patent application 2023-044202, filed Mar. 20, 2023, the entire contents of each of which being incorporated herein by reference.

### TECHNICAL FIELD

The present disclosure relates to a filter device, and more particularly relates to a technique of improving the attenuation characteristics in a non-pass band of a filter device.

### BACKGROUND ART

Japanese Patent No. 4738218 (Patent Document 1) discloses a low pass filter as an example of a multilayer electronic component. In the low pass filter according to Patent Document 1, at least some of a plurality of ground side electrodes disposed on a side surface of a multilayer body are not connected to an insulating substrate, to thereby control the frequency of an attenuation pole generated by a parasitic inductor.

### CITATION LIST

### Patent Document

Patent Document 1: Japanese Patent No. 4738218

### SUMMARY

### Technical Problems

In a low pass filter, unintended spurious may be generated in a non-pass band on a higher frequency side than a pass band by the stray capacitance of an inductor that constitutes a resonance circuit and/or the structural asymmetry due to manufacturing variations or the like. As a result, the attenuation characteristics may deteriorate in the non-pass band.

In recent years, portable communication devices represented by smartphones and cellular phones have adopted a configuration to use radio waves in a frequency band for microwaves at 6 GHz or lower for Wi-Fi or the like and radio waves in a frequency band for millimeter waves at 28 GHZ, 39 GHz, and the like corresponding to the 5G communication standard. In such a communication device, when spurious such as that described above is generated in the millimeter wave bands in a low pass filter for use in a circuit that processes radio waves in the microwave bands, noise may be generated in the millimeter wave bands because of a deterioration in attenuation characteristics in the frequency bands, which may lead to a deterioration in communication quality.

The present disclosure has been made to address the above issue, and is directed to preventing or reducing a deterioration in attenuation characteristics due to spurious generated in a filter device.

### Solutions to Problems

An aspect of the present disclosure provides a filter device including an input terminal, an output terminal, a ground terminal, and a first resonator connected to the input terminal and the output terminal. The first resonator includes a first terminal connected to the input terminal, a second terminal connected to the output terminal, first and second inductors, and first to third capacitors. One end of the first inductor is connected to the first terminal. One end of the second inductor is connected to the second terminal, and the other end thereof is connected to the other end of the first inductor. One end of the first capacitor is connected to the first terminal. One end of the second capacitor is connected to the second terminal, and the other end thereof is connected to the other end of the first capacitor. The third capacitor is connected between the other end of the first inductor and the other end of the first capacitor.

Another aspect of the present disclosure provides a filter device including a multilayer body in which a plurality of dielectrics are stacked, an input terminal, an output terminal, a ground terminal, first and second paths, and first to fourth capacitor electrodes. The first path is connected to the input terminal. The second path is connected to the output terminal. The first capacitor electrode is connected to the first path. The second capacitor electrode is connected to the second path. The third capacitor electrode is connected to the first and second paths. When viewed in plan view from a stacking direction of the multilayer body, at least a part of the first capacitor electrode, at least a part of the second capacitor electrode, and at least a part of the third capacitor electrode are superposed on the fourth capacitor electrode.

### Advantageous Effects

In the filter device according to the present disclosure, in the filter device including an LC parallel resonator connected between the input terminal and the output terminal, a capacitor (third capacitor) for spurious adjustment is disposed between an intermediate portion of the inductors and an intermediate portion of the capacitors of the resonator. By setting the capacitance of the capacitor for adjustment to be larger than the stray capacitance of the inductor, the frequency of spurious to be generated is reduced, which makes it possible to generate spurious in a frequency band other than frequency bands to be used. Thus, it is possible to prevent or reduce a deterioration in attenuation characteristics due to spurious generated in the filter device.

### BRIEF DESCRIPTION OF DRAWINGS

FIG. 1 is an equivalent circuit diagram of a filter device according to a first embodiment.

FIG. 2 is a perspective view of an outer shape of the filter device according to the first embodiment.

FIG. 3 is an exploded perspective view illustrating an example of a multilayer structure of the filter device in FIG. 2.

FIG. 4 is an equivalent circuit diagram of a filter device according to a comparative example.

FIG. 5 illustrates filter characteristics of the filter devices according to the first embodiment and the comparative example.

FIG. 6 is a first diagram for explaining the reason for generation of spurious.

FIG. 7 is a second diagram for explaining the reason for the generation of spurious.

FIG. 8 illustrates the filter characteristics for a case where line lengths of inductors of a resonator are adjusted.

FIG. 9 is an equivalent circuit diagram of a filter device according to a first modification.

FIG. 10 is an equivalent circuit diagram of a filter device according to a second modification.

FIG. 11 is an equivalent circuit diagram of a filter device according to a second embodiment.

FIG. 12 is an exploded perspective view illustrating an example of a multilayer structure of the filter device according to the second embodiment.

FIG. 13 is a first diagram for explaining the reason that a level of spurious is adjustable.

FIG. 14 is a second diagram for explaining the reason that the level of spurious is adjustable.

FIG. 15 illustrates filter characteristics of the filter device according to the second embodiment.

FIG. 16 is an equivalent circuit diagram of a filter device according to a third modification.

FIG. 17 is an equivalent circuit diagram of a filter device according to a fourth modification.

FIG. 18 is an equivalent circuit diagram of a filter device according to a fifth modification.

FIG. 19 is an equivalent circuit diagram of a filter device according to a third embodiment.

FIG. 20 illustrates filter characteristics of the filter device according to the third embodiment.

FIG. 21 is an equivalent circuit diagram of a filter device according to a fourth embodiment.

FIG. 22 illustrates filter characteristics of the filter device according to the fourth embodiment.

FIG. 23 is an equivalent circuit diagram of a filter device according to a sixth modification.

FIG. 24 illustrates filter characteristics of the filter device according to the sixth modification.

### DESCRIPTION OF EMBODIMENTS

Embodiments of the present disclosure will be described in detail below with reference to the drawings. Like or equivalent portions in the drawings are given like reference signs to omit description thereof.

### First Embodiment

FIG. 1 is an equivalent circuit diagram of a filter device 100 according to a first embodiment. The filter device 100 includes an input terminal T1, an output terminal T2, a ground terminal GND, resonators RC0 and RC1, capacitors C1 and C2, and an inductor L31. The resonator RC0 includes an inductor L11 and a capacitor C11. The resonator RC1 includes capacitors C21 to C23 and inductors L21 and L22.

The resonator RC0 is connected to the input terminal T1. More specifically, one end of the inductor L11 is connected to the input terminal T1, and the capacitor C11 is connected in parallel with the inductor L11.

One end of the inductor L31 is connected to the output terminal T2. A terminal N1 (first terminal) of the resonator RC1 is connected to the other end of the inductor L11 included in the resonator RC0, and a terminal N2 (second terminal) of the resonator RC1 is connected to the other end of the inductor L31.

In the resonator RC1, the inductors L21 and L22 connected in series are connected between the terminal N1 connected to the inductor L11 and the terminal N2 connected to the inductor L31. One end of the capacitor C21 is connected to the terminal N1, and the other end thereof is connected to one end of the capacitor C22. The other end of the capacitor C22 is connected to the terminal N2. That is, the capacitors C21 and C22 connected in series are connected in parallel with the inductors L21 and L22 connected in series. The capacitor C23 is connected between a first connection node N11 between the inductor L21 and the inductor L22 and a second connection node N12 between the capacitor C21 and the capacitor C22.

The capacitor C1 is connected between the terminal N1 of the resonator RC1 and the ground terminal GND. The capacitor C2 is connected between the terminal N2 of the resonator RC1 and the ground terminal GND. That is, the filter device 100 constitutes a so-called fifth-order low pass filter.

The expression “connected” as used herein means not only a case where two elements are directly connected but also a case where two elements are connected via another element.

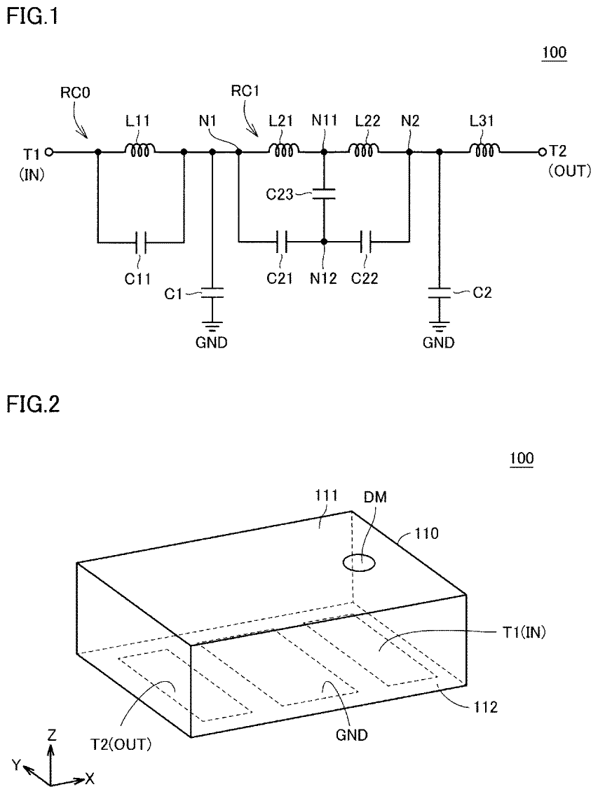

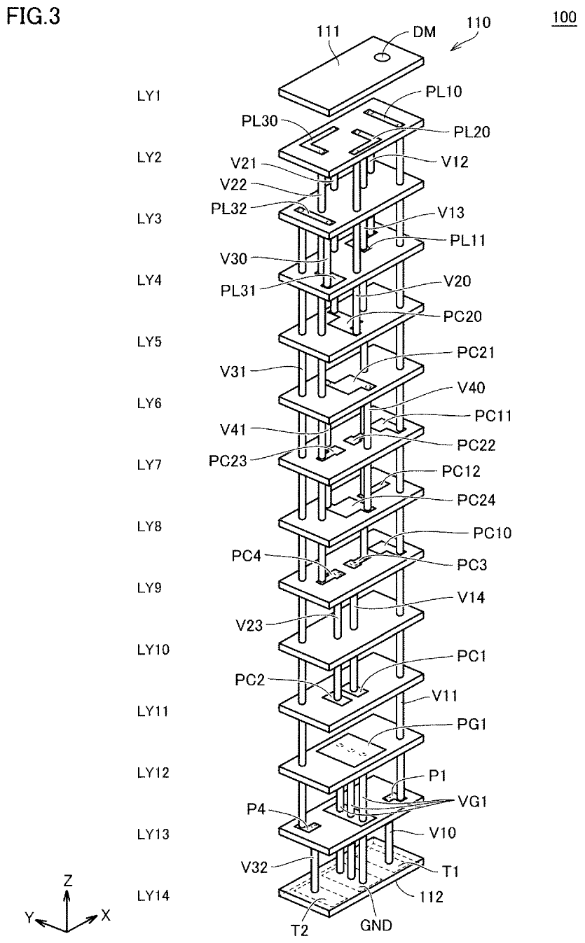

Next, the structure of the filter device 100 will be described with reference to FIGS. 2 and 3. FIG. 2 is a perspective view of an outer shape of the filter device 100, and FIG. 3 is an exploded perspective view illustrating an example of a multilayer structure of the filter device 100.

With reference to FIGS. 2 and 3, the filter device 100 includes a multilayer body 110 of a rectangular parallelepiped or a substantially rectangular parallelepiped in which a plurality of dielectric layers LY1 to LY14 are stacked in the stacking direction. The dielectric layers LY1 to LY14 are formed of a ceramic such as low-temperature co-fired ceramics (LTCC) or a resin, for example. The inductors and the capacitors illustrated in FIG. 1 are constituted by a plurality of electrodes provided in the dielectric layers and a plurality of vias provided between the dielectric layers inside the multilayer body 110. The term “via” as used herein refers to a columnar conductor provided in a dielectric layer to connect electrodes provided in different dielectric layers. The via is formed by conductive paste, plating, and/or a metal pin, for example.

In the following description, the stacking direction of the dielectric layers LY1 to LY14 in the multilayer body 110 is defined as a “Z-axis direction”, the direction perpendicular to the Z-axis direction and along the long sides of the multilayer body 110 is defined as an “X-axis direction”, and the direction along the short sides of the multilayer body 110 is defined as a “Y-axis direction”. In the following, the positive direction and the negative direction of the Z-axis in the drawings are occasionally referred to as an upper side and a lower side, respectively.

A direction mark DM for specifying the direction of the filter device 100 is disposed on an upper surface 111 (dielectric layer LY1) of the multilayer body 110. External terminals (input terminal T1, output terminal T2, and ground terminal GND) for connecting the filter device 100 to an external device are disposed on a lower surface 112 (dielectric layer LY14) of the multilayer body 110. The input terminal T1, the output terminal T2, and the ground terminal GND are each a flat plate electrode having a substantially rectangular shape, and are land grid array (LGA) terminals disposed regularly on the lower surface 112 of the multilayer body 110.

The input terminal T1 is disposed along the short side of the lower surface 112 in the positive direction of the X-axis. The output terminal T2 is disposed along the short side of the lower surface 112 in the negative direction of the X-axis. The ground terminal GND is disposed between the input terminal T1 and the output terminal T2 in the X-axis direction.

The input terminal T1 is connected to a flat plate electrode P1 disposed in the dielectric layer LY13 by a via V10. The flat plate electrode P1 is an electrode having a substantially L-shape when viewed in plan view from the stacking direction (Z-axis direction). The flat plate electrode P1 is connected to a capacitor electrode PC10 disposed in the dielectric layer LY9, a capacitor electrode PC11 disposed in the dielectric layer LY7, and a flat plate electrode PL10 disposed in the dielectric layer LY2 by a via V11.

The flat plate electrode PL10 disposed in the dielectric layer LY2 is an electrode in a linear band shape extending in the Y-axis direction. The via V11 is connected to a first end portion of the flat plate electrode PL10, and a via V12 is connected to a second end portion thereof.

The via V12 is connected to a flat plate electrode PL11 disposed in the dielectric layer LY4. The flat plate electrode PL11 is an electrode having a substantially L-shape when viewed in plan view from the stacking direction. The via V12 is connected to a first end portion of the flat plate electrode PL11, and a via V13 is connected to a second end portion thereof.

The via V13 is connected to a flat plate electrode PL20 disposed in the dielectric layer LY2. The via V13 is also connected to a capacitor electrode PC22 disposed in the dielectric layer LY7, a capacitor electrode PC12 disposed in the dielectric layer LY8, and a capacitor electrode PC3 disposed in the dielectric layer LY9.

The capacitor electrode PC3 is connected to a capacitor electrode PC1 disposed in the dielectric layer LY11 via a via V14. When viewed in plan view from the stacking direction, at least a part of the capacitor electrode PC1 is superposed on a ground electrode PG1 disposed in the dielectric layer LY12. The ground electrode PG1 is connected to the ground terminal GND on the lower surface 112 by a plurality of vias VG1. That is, the capacitor C1 in FIG. 1 is constituted by the capacitor electrode PC1 and the ground electrode PG1. The inductor L11 in FIG. 1 is formed by a first path extending from the input terminal T1 to the capacitor electrode PC1 via the vias V10 to V14, the capacitor electrode PC3, and the flat plate electrodes P1, PL10, and PL11.

The capacitor electrode PC11 in the dielectric layer LY7 and the capacitor electrode PC10 in the dielectric layer LY9 are electrodes of the same shape having a substantially L-shape, and are superposed on each other when viewed in plan view from the stacking direction. The capacitor electrodes PC10 and PC11 are each partially superposed on the capacitor electrode PC12 in the dielectric layer LY8 when viewed in plan view from the stacking direction. That is, the capacitor C11 in FIG. 1 is constituted by the capacitor electrodes PC10 to PC12.

The flat plate electrode PL20 is an electrode having a substantially L-shape when viewed in plan view from the stacking direction. The via V13 is connected to a first end portion of the flat plate electrode PL20, and a via V20 is connected to a second end portion thereof. The via V20 is connected to a capacitor electrode PC20 disposed in the dielectric layer LY5. A via V21 is also connected to the capacitor electrode PC20. The via V21 is connected to a flat plate electrode PL30 disposed in the dielectric layer LY2.

The flat plate electrode PL30 is an electrode having a substantially L-shape when viewed in plan view from the stacking direction. The via V21 is connected to a first end portion of the flat plate electrode PL30, and a via V22 is connected to a second end portion thereof. The via V22 is connected to a flat plate electrode PL31 disposed in the dielectric layer LY4, a capacitor electrode PC23 disposed in the dielectric layer LY7, and a capacitor electrode PC4 disposed in the dielectric layer LY9.

The capacitor electrode PC4 is connected to a capacitor electrode PC2 disposed in the dielectric layer LY11 via a via V23. When viewed in plan view from the stacking direction, at least a part of the capacitor electrode PC2 is superposed on the ground electrode PG1 disposed in the dielectric layer LY12. That is, the capacitor C2 in FIG. 1 is constituted by the capacitor electrode PC2 and the ground electrode PG1.

The flat plate electrode PL31 in the dielectric layer LY4 is an electrode having a substantially L-shape when viewed in plan view from the stacking direction. The via V21 is connected to a first end portion of the flat plate electrode PL31, and a via V30 is connected to a second end portion thereof. The via V30 is connected to a flat plate electrode PL32 disposed in the dielectric layer LY3. The flat plate electrode PL32 is an electrode in a linear band shape extending in the Y-axis direction. The via V30 is connected to a first end portion of the flat plate electrode PL32, and a via V31 is connected to a second end portion thereof. The via V31 is connected to the output terminal T2 on the lower surface 112 via a flat plate electrode P4 disposed in the dielectric layer LY13 and a via V32.

The inductor L31 in FIG. 1 is formed by a second path from the output terminal T2 to the capacitor electrode PC2 via the vias V22, V23, and V30 to V32, the capacitor electrode PC4, and the flat plate electrodes P4, PL31, and PL32. The inductor L21 in FIG. 1 is formed by a second conductive path that leads from the flat plate electrode PL11 to the capacitor electrode PC20 via the vias V13 and V20 and the flat plate electrode PL20. The inductor L22 in FIG. 1 is constituted by a path that leads from the capacitor electrode PC20 to the flat plate electrode PL31 via the vias V21 and V22 and the flat plate electrode PL30.

At least a part of the capacitor electrode PC20 in the dielectric layer LY5 is superposed on the capacitor electrode PC21 disposed in the dielectric layer LY6 when viewed in plan view from the stacking direction. The capacitor electrode PC21 is connected to a capacitor electrode PC24 disposed in the dielectric layer LY8 by vias V40 and V41. The capacitor electrodes PC21 and PC24 are partially superposed on the capacitor electrodes PC22 and PC23 disposed in the dielectric layer LY7 and the capacitor electrodes PC3 and PC4 disposed in the dielectric layer LY9 when viewed in plan view from the stacking direction.

The capacitor C21 in FIG. 1 is constituted by the capacitor electrodes PC21 and PC24 and the capacitor electrodes PC22 and PC3. The capacitor C22 in FIG. 1 is constituted by the capacitor electrodes PC21 and PC24 and the capacitor electrodes PC23 and PC4. Further, the capacitor C23 in FIG. 1 is constituted by the capacitor electrode PC20 and the capacitor electrode PC21.

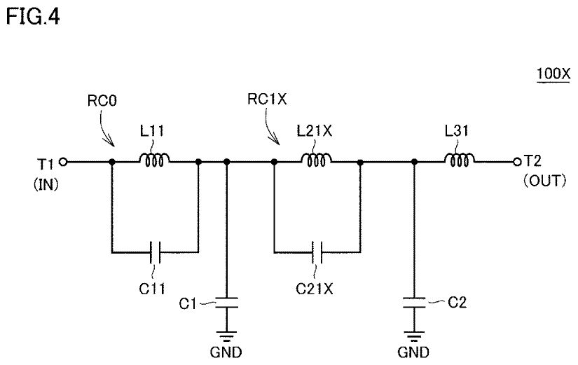

The features of the filter device 100 according to the first embodiment will be described with reference to the configuration of a filter device according to a comparative example. FIG. 4 is an equivalent circuit diagram of a filter device 100X according to a comparative example. In the filter device 100X according to the comparative example, the resonator RC1 in the filter device 100 has been replaced with a resonator RC1X. The resonator RC1X has a configuration in which an inductor L21X and a capacitor C21X are connected in parallel. In other words, the filter device 100X corresponds to the configuration of the filter device 100 according to the first embodiment from which the capacitor C23 of the resonator RC1 has been removed.

In a filter device in which each element is disposed in a multilayer body such as that in FIGS. 2 and 3, in general, stray capacitance tends to be generated for each element. For an inductor, in particular, an unintended resonance circuit may be formed by the stray capacitance and/or the structural asymmetry due to manufacturing variations or the like, and spurious may be generated by the resonant frequency of the resonance circuit. Since the stray capacitance is a relatively small capacitance, the frequency of spurious to be generated is generally higher than the pass band of the low pass filter.

In recent years, portable communication devices represented by smartphones and cellular phones have adopted a configuration to use radio waves in a frequency band for microwaves at 6 GHz or lower for Wi-Fi or the like and radio waves in a frequency band for millimeter waves at 28 GHZ, 39 GHz, and the like corresponding to the 5G communication standard. In such a communication device, when spurious such as that described above is generated in the millimeter wave bands in a low pass filter for use in a circuit that processes radio waves in the microwave bands, noise may be generated in the millimeter wave bands because of a deterioration in attenuation characteristics in the frequency bands, which may lead to a deterioration in communication quality.

It is difficult to estimate the stray capacitance to be generated for an inductor in the design stage, and it is also difficult to prevent the generation of spurious by preventing or reducing the generation of the stray capacitance itself. Thus, in the filter device 100 according to the first embodiment, the frequency of spurious to be generated because of the stray capacitance is reduced so that spurious is generated in a non-pass band between two frequency bands of target radio waves to be used for communication, by incorporating a capacitor (capacitor C23 in FIG. 1) having a relatively large capacitance compared to the stray capacitance in the resonator in advance. With such a configuration, it is possible to prevent or reduce a deterioration in attenuation characteristics due to unintended spurious in the target pass band.

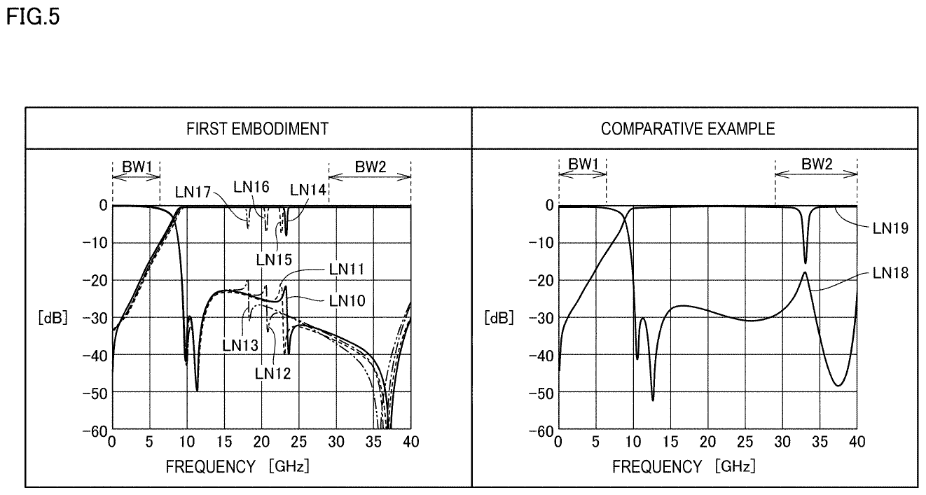

FIG. 5 illustrates filter characteristics of the filter device 100 according to the first embodiment and the filter device 100X according to the comparative example. The left part of FIG. 5 indicates the results of simulating the pass characteristics of the filter device 100 according to the first embodiment, and the right part thereof indicates the results of simulating the pass characteristics of the filter device 100X according to the comparative example.

In each graph of the pass characteristics, the horizontal axis indicates the frequency, and the vertical axis indicates the return loss (LN14 to LN17 and LN19) and the insertion loss (lines LN10 to LN13 and LN18). In the pass characteristics of the filter device 100, a graph obtained by varying the capacitance value of the capacitor C23 is also indicated. A frequency band BW1 of a signal targeted by the filter device 100 according to the first embodiment is the range of the microwave bands of 0 to 6 GHz, for example, and a frequency band BW2 of another signal in the communication device is the range of the millimeter wave bands of 27.5 GHZ to 40 GHZ.

With reference to FIG. 5, in the filter device 100X according to the comparative example, a good insertion loss is obtained in the frequency band BW1 of microwaves, as indicated by the line LN18 in the right part. However, spurious is generated around 33 GHz in the frequency band BW2 of millimeter waves, and the attenuation decreases and the attenuation characteristics deteriorate at the spurious portion.

On the contrary, in the filter device 100 according to the first embodiment, spurious is generated, but spurious is generated at a frequency (17 GHz to 24 GHZ) between the two frequency bands BW1 and BW2 of signals. Consequently, the attenuation is ensured in the frequency band BW2 of millimeter waves, and desired attenuation characteristics are obtained.

As indicated in the left part of FIG. 5, as the capacitance of the capacitor C23 in FIG. 1 is increased, the frequency of spurious to be generated is reduced to be closer to the attenuation pole of the filter device 100. The capacitance of the capacitor C23 is selected as appropriate in consideration of the effect on the two frequency bands BW1 and BW2.

The magnitude of spurious to be generated varies in accordance with the structural asymmetry of the resonator RC1. Specifically, the effect of spurious increases when there is a difference between the resonant frequency for a case where the resonator is constituted by the inductor L21 and the capacitor C21 and the resonant frequency for a case where the resonator is constituted by the inductor L22 and the capacitor C22 in FIG. 1.

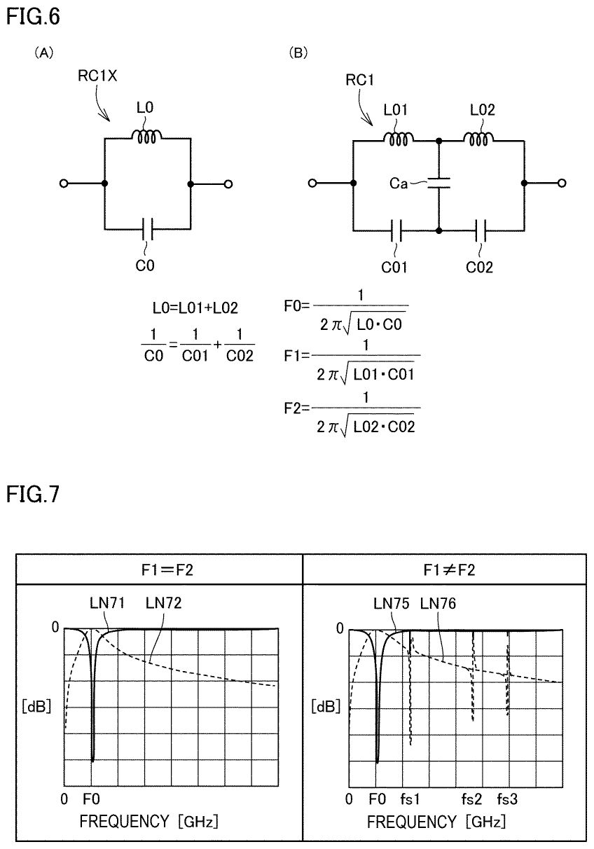

Here, the reason for the generation of spurious will be described in more detail with reference to FIGS. 6 and 7. The left part (A) of FIG. 6 illustrates a portion of the resonator RC1X according to the comparative example, and the right part (B) thereof illustrates a portion of the resonator RC1 in the filter device 100 according to the first embodiment. FIG. 7 indicates the insertion loss (solid lines LN71 and LN75) and the return loss (wavy lines LN72 and LN76) in the resonator RC1.

The inductance value of the inductor L21X in the resonator RC1X is defined as L0, and the capacitance value of the capacitor C21X therein is defined as C0. The inductance values of the inductors L21 and L22 in the resonator RC1 are defined as L01 and L02, respectively, and the capacitance values of the capacitors C21 to C23 are defined as C01, C02, and Ca, respectively. The inductance value L0 of the inductor L21X is equal to the sum of the inductance values L01 and L02 of the inductors L21 and L22 (L0=L01+L02). The reciprocal of the capacitance value C0 of the capacitor C21X is equal to the sum of the reciprocals of the capacitance values C01 and C02 of the capacitors C21 and C22 (1/C0=1/C01+1/C02).

At this time, a resonant frequency F0 of the resonator RC1X can be represented by the following equation (1).

F0=1/{2π(L0·C0)^{1/2}} (1)

Since L0=L01+L02 and 1/C0=1/C01+1/C02 are met as described above, the resonant frequency of the resonator RC1 as a whole is represented as F0.

When the resonant frequency of the resonator constituted by the inductor L21 and the capacitor C21 in the resonator RC1 is defined as F1 and the resonant frequency of the resonator constituted by the inductor L22 and the capacitor C22 is defined as F2, these resonant frequencies can be represented by the following equation (2) and equation (3), respectively.

F1=1/{2π(L01·C01)^{1/2}} (2)

F2=1/{2π(L02·C02)^{1/2}} (3)

When the above resonant frequencies F1 and F2 are equal (F1=F2) in the configuration of the resonator RC1, no spurious is generated on the higher frequency side than the resonant frequency F0 of the entire resonator as indicated in the left part of FIG. 7. In the actual structure of the resonator, a stray capacitance Ca represented as the capacitor C23 may be generated by the limitation on the size of the device or errors in the arrangement and processing of electrodes that form the elements. When the element parameters are unbalanced and the resonant frequencies F1 and F2 are different from each other (F1≠F2) by the effect of the stray capacitance, spurious may be generated on the higher frequency side than the resonant frequency F0, as indicated in the right part of FIG. 7.

When the magnitude of the stray capacitance Ca fluctuates, a frequency fs of the spurious varies. Specifically, as the stray capacitance Ca becomes larger, the frequency fs of the spurious becomes gradually lower in the order of fs3, fs2, and fs1 toward F0. The resonant frequency F0 of the entire resonator does not substantially vary even if the stray capacitance Ca varies.

In general, a stray capacitance generated without intention is small, and therefore spurious is generated on the relatively high frequency side. In the filter device 100 according to the first embodiment, the capacitor C23 having a larger capacitance value than the stray capacitance is connected in advance to the portion of the above stray capacitance Ca, and therefore the effect of the capacitor C23 on the frequency of spurious is more dominant than that of the stray capacitance generated without intention. In other words, the frequency of spurious can be adjusted while intentionally generating spurious by adjusting the capacitance value Ca of the capacitor C23.

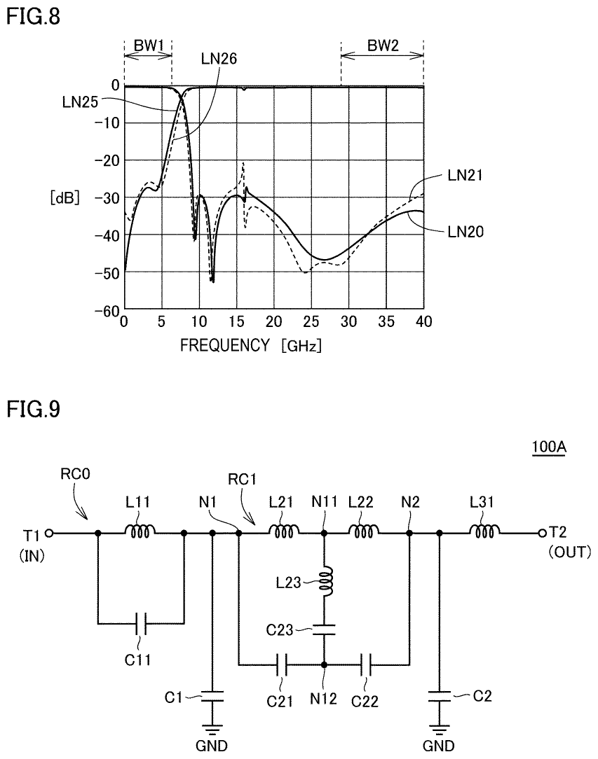

FIG. 8 illustrates the filter characteristics for a case where the resonant frequencies F1 and F2 indicated in FIG. 6 are adjusted by adjusting line lengths of the inductors L21 and L22 of the resonator RC1 in the filter device 100. In FIG. 8, solid lines LN20 and LN25 indicate the filter characteristics after the resonant frequencies F1 and F2 are adjusted to approximately the same degree by adjusting the line lengths, and broken lines LN21 and LN26 indicate the filter characteristics before adjusting the line lengths. As indicated in FIG. 8, the level of spurious generated around 16 GHz has been reduced by adjusting the resonant frequencies F1 and F2 to approximately the same degree by adjusting the line lengths.

In this manner, in an LC parallel resonator constituting a filter device, the frequency at which spurious is generated can be intentionally adjusted by disposing a capacitor between an intermediate portion of the inductors and an intermediate portion of the capacitors of the resonator. Further, in the resonator, the level of spurious can be reduced by adjusting the lengths of two inductors connected to the capacitor for spurious adjustment and adjusting the resonant frequencies F1 and F2 of resonators formed on the input side and the output side of the capacitor to approximately the same degree.

While the capacitor for spurious adjustment is disposed for the resonator RC1 in the first embodiment, the capacitor for spurious adjustment may be disposed for the resonator RC0 when spurious generated by the resonator RC0 is superposed on the pass band of a target signal.

The “resonator RC1” according to the first embodiment corresponds to the “first resonator” according to the present disclosure. The “inductor L21”, “inductor L22”, “inductor L11”, and “inductor L31” according to the first embodiment correspond to the “first inductor” to “fourth inductor”, respectively, according to the present disclosure. The “capacitor C21”, “capacitor C22”, and “capacitor C23” according to the first embodiment correspond to the “first capacitor” to “third capacitor”, respectively, according to the present disclosure. The “capacitor C1” and “capacitor C2” according to the first embodiment correspond to the “fifth capacitor” and “sixth capacitor”, respectively, according to the present disclosure. The “capacitor C11” according to the first embodiment corresponds to the “seventh capacitor” according to the present disclosure. The “frequency band BW1” and “frequency band BW2” according to the first embodiment correspond to the “first frequency band” and “second frequency band”, respectively, according to the present disclosure.

The “capacitor electrode PC22”, “capacitor electrode PC23”, “capacitor electrode PC20”, and “capacitor electrode PC21” according to the first embodiment correspond to the “first capacitor electrode” to “fourth capacitor electrode”, respectively, according to the present disclosure.

### (First Modification)

In the first embodiment, a capacitor for spurious adjustment is disposed between an intermediate portion of the inductors and an intermediate portion of the capacitors of the LC parallel resonator. In a modification, the frequency of spurious is adjusted by disposing an LC series resonator between an intermediate portion of the inductors and an intermediate portion of the capacitors of the LC parallel resonator.

FIG. 9 is an equivalent circuit diagram of a filter device 100A according to a first modification. In the filter device 100A, an inductor L23 is added to a portion of the capacitor C23 in the configuration of the filter device 100 illustrated in FIG. 1. More specifically, the inductor L23 is disposed between the first connection node N11 between the inductor L21 and the inductor L22 and the capacitor C23. The configuration in FIG. 9 is otherwise the same as that in FIG. 1, and elements that are the same as those in FIG. 1 will not be described.

In this manner, also when an LC series resonator is used as a spurious frequency adjustment circuit, the frequency of spurious to be generated can be adjusted by adjusting the resonant frequency of the LC series resonator. In particular, the capacitance of the capacitor needed for a frequency adjustment circuit can be reduced by using the LC series resonator instead of using only the capacitor, which makes it possible to reduce the device size.

The arrangement of the inductor L23 and the capacitor C23 may be reversed. That is, the capacitor C23 may be connected to the first connection node N11, and the inductor L23 may be connected between the capacitor C23 and the second connection node N12.

### (Second Modification)

While the filter device is a fifth-order low pass filter in the first embodiment and the first modification, the features of the present disclosure are also applicable to a third-order low pass filter.

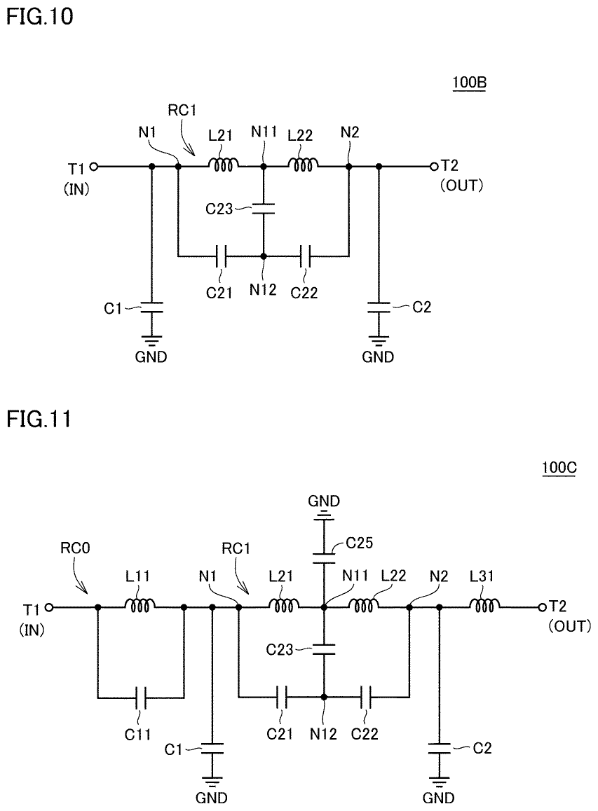

FIG. 10 is an equivalent circuit diagram of a filter device 100B according to a second modification. In the filter device 100B, the resonator RC0 and the inductor L31 have been removed from the filter device 100 illustrated in FIG. 1. That is, the filter device 100B is a third-order low pass filter composed of the resonator RC1 and the capacitors C1 and C2 which are shunt capacitors.

Also with such a configuration, there is a possibility that spurious is generated by the stray capacitance of the inductor constituting the LC parallel resonator. Therefore, it is possible to prevent or reduce a deterioration in attenuation characteristics in the non-pass band of the low pass filter by providing a capacitor that connects a center portion of the inductors and a center portion of the capacitors constituting the parallel resonator and making the capacitance of the capacitor larger than the stray capacitance to intentionally reduce the frequency of spurious so that the spurious is not superposed on the pass band of a signal on the high frequency side.

### Second Embodiment

In a second embodiment, a circuit that reduces the level of spurious is added to the configuration according to the first embodiment.

FIG. 11 is an equivalent circuit diagram of a filter device 100C according to a second embodiment. With reference to FIG. 11, in the filter device 100C, a capacitor C25 is added between the capacitor C23 for adjusting the frequency of spurious in the resonator RC1 of the filter device 100 according to the first embodiment and the ground terminal GND. Elements of the filter device 100C in FIG. 11 that are the same as those of the filter device 100 in FIG. 1 will not be described.

More specifically, the capacitor C25 is disposed between the first connection node N11 between the inductor L21 and the inductor L22 and the ground terminal GND.

In this manner, the potential of the capacitor C23 for spurious adjustment relative to the ground potential can be specified by the capacitor C25. Further, the anti-resonant frequency and the resonant frequency of spurious can be brought closer by adjusting the magnitude of the capacitor C25 after adjusting the frequency of spurious using the capacitor C23, which makes it possible to reduce the level of spurious through the cancellation of an anti-resonant point and a resonant point.

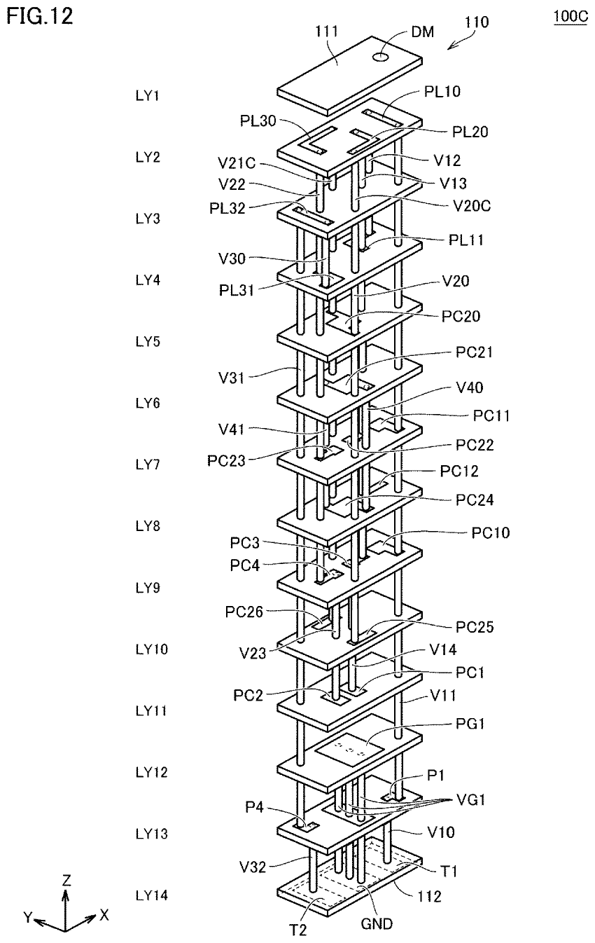

FIG. 12 is an exploded perspective view illustrating an example of a multilayer structure of the filter device 100C according to the second embodiment. In FIG. 12, the vias V20 and V21 in the exploded perspective view of the filter device 100 illustrated in FIG. 3 have been replaced with vias V20C and V21C, respectively. Further, capacitor electrodes PC25 and PC26 are connected to end portions of the vias V20C and V21C, respectively.

More particularly, the via V20C is connected not only to the flat plate electrode PL20 in the dielectric layer LY2 and the capacitor electrode PC20 in the dielectric layer LY5, but also to the capacitor electrode PC25 disposed in the dielectric layer LY10. Similarly, the via V21C is connected not only to the flat plate electrode PL30 in the dielectric layer LY2 and the capacitor electrode PC20 in the dielectric layer LY5, but also to the capacitor electrode PC26 disposed in the dielectric layer LY10.

The capacitor electrodes PC25 and PC26 are each an electrode in a band shape extending in the X-axis direction, and at least a part of each of the capacitor electrodes PC25 and PC26 is superposed on the ground electrode PG1 in the dielectric layer LY12 when viewed in plan view from the stacking direction. That is, the capacitor C25 in FIG. 11 is constituted by the capacitor electrodes PC25 and PC26 and the ground electrode PG1.

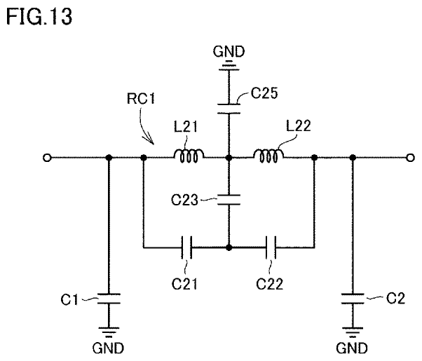

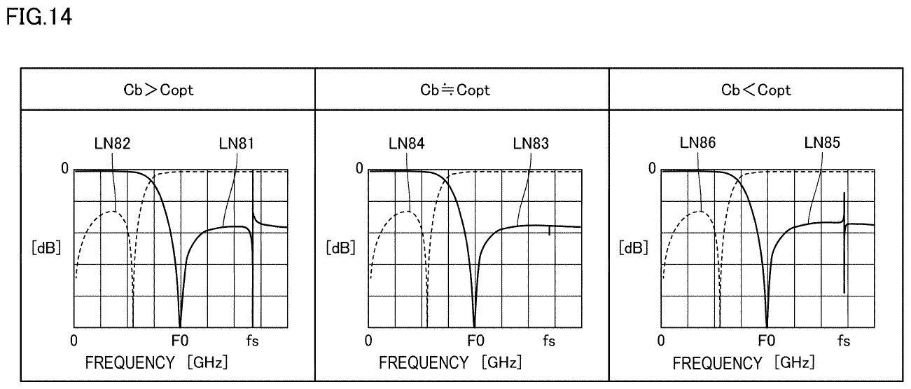

Next, variations in the level of spurious due to the magnitude of the capacitor C25 will be described with reference to FIGS. 13 and 14. FIG. 13 illustrates a portion of the resonator RC1 and the capacitors C1 and C2, in the filter device 100C illustrated in FIG. 11. In other words, FIG. 13 illustrates a low pass filter obtained by removing the resonator RC0 and the inductor L31 from the filter device 100C.

FIG. 14 indicates results of simulating the insertion loss (solid lines LN81, LN83, and LN85) and the return loss (broken lines LN82, LN84, and LN86) at the time when a capacitance value Cb of the capacitor C25 is varied in the filter in FIG. 13. The center part of FIG. 14 indicates a case where the capacitance value Cb of the capacitor C25 is in the vicinity of a specific capacitance value Copt (Cb≈Copt). The left part indicates a case where the capacitance value Cb is larger than the capacitance value Copt (Cb>Copt), and the right part indicates a case where the capacitance value Cb is smaller than the capacitance value Copt (Cb<Copt).

As indicated in FIG. 14, the level of spurious is low when the capacitance value Cb of the capacitor C25 is approximately the same as the capacitance value Copt. When the capacitance value Cb is larger than the capacitance value Copt (left part), a resonant point is generated on the lower frequency side than the frequency fs at which spurious is generated, and an anti-resonant point is generated on the higher frequency side than the frequency fs at which spurious is generated. When the capacitance value Cb is smaller than the capacitance value Copt (right part), on the other hand, an anti-resonant point is generated on the lower frequency side than the frequency fs at which spurious is generated, and a resonant point is generated on the higher frequency side than the frequency fs at which spurious is generated. That is, the capacitance value Copt is a capacitance value for a case where a resonant point and an anti-resonant point at which spurious is generated coincide with each other. Consequently, the amplitude at the anti-resonant point which hinders attenuation is canceled out by the amplitude at the resonant point, which reduces the level of spurious.

As indicated in FIG. 14, the resonant frequency F0 of the entire filter and the frequency fs of spurious do not substantially vary even when the capacitance value Cb is varied. That is, the level of spurious can be adjusted, while the effects on the resonant frequency F0 of the filter device and the frequency fs of spurious are prevented or reduced, by varying the capacitance value Cb of the capacitor C25.

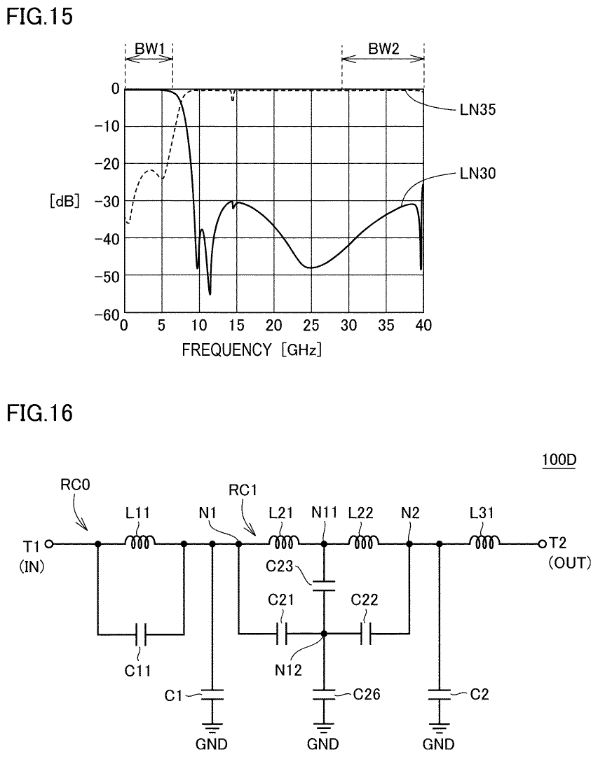

FIG. 15 illustrates filter characteristics of the filter device 100C according to the second embodiment. In FIG. 15, a solid line LN30 indicates the insertion loss, and a broken line LN35 indicates the return loss. Upon comparison with FIGS. 5 and 8 for the first embodiment, it can be seen that the level of spurious generated around 15 GHz is significantly reduced.

As discussed above, the capacitance value of the capacitor C25 has an optimum value Copt for the configuration of the filter device, and the level of spurious increases when the capacitance value is larger or smaller than the optimum value. When the capacitance value is larger than the optimum value, a resonant point and an anti-resonant point of spurious appear in this order from the low frequency side toward the high frequency side. When the capacitance value is smaller than the optimum value, conversely, an anti-resonant point and a resonant point of spurious appear in this order from the low frequency side toward the high frequency side. It is possible to reduce the level of spurious through the cancellation of an anti-resonant point and a resonant point by setting the capacitance value of the capacitor C25 such that the resonant point and the anti-resonant point of spurious to be generated are brought closer.

As described above, the level of spurious to be generated can be reduced by adding a capacitor between the capacitor for adjusting the frequency of spurious and the ground terminal and adjusting the capacitance value of the capacitor.

The “capacitor C25” according to the second embodiment corresponds to an example of the “fourth capacitor” according to the present disclosure. The “capacitor electrode PC25” and “capacitor electrode PC26” according to the second embodiment correspond to the “fifth capacitor electrode” and “sixth capacitor electrode”, respectively, according to the present disclosure.

### (Third Modification)

In the second embodiment, a capacitor is added between the electrode, on the side of the inductors L21 and L22, of the capacitor C23 for adjusting the frequency of spurious and the ground terminal GND. In a third modification, a capacitor is added between the electrode, on the side of the capacitors C21 and C22, of the capacitor C23 and the ground terminal GND.

FIG. 16 is an equivalent circuit diagram of a filter device 100D according to a third modification. With reference to FIG. 16, in the filter device 100D, a capacitor C26 is added between the capacitor C23 in the resonator RC1 of the filter device 100 and the ground terminal GND. More specifically, the capacitor C26 is disposed between the second connection node N12 between the capacitor C21 and the capacitor C22 and the ground terminal GND.

Also with such a configuration, the potential of the capacitor C23 for spurious adjustment relative to the ground potential can be specified. Further, the anti-resonant frequency and the resonant frequency of spurious can be brought closer by adjusting the magnitude of the capacitor C26 after adjusting the frequency of spurious using the capacitor C23, which makes it possible to reduce the level of spurious through the cancellation of an anti-resonant point and a resonant point.

The “capacitor C26” according to the third modification corresponds to an example of the “fourth capacitor” according to the present disclosure.

### (Fourth Modification)

In a fourth modification, an LC series resonator is disposed at a portion of the shunt capacitor for adjusting the level of spurious in the configuration according to the second embodiment.

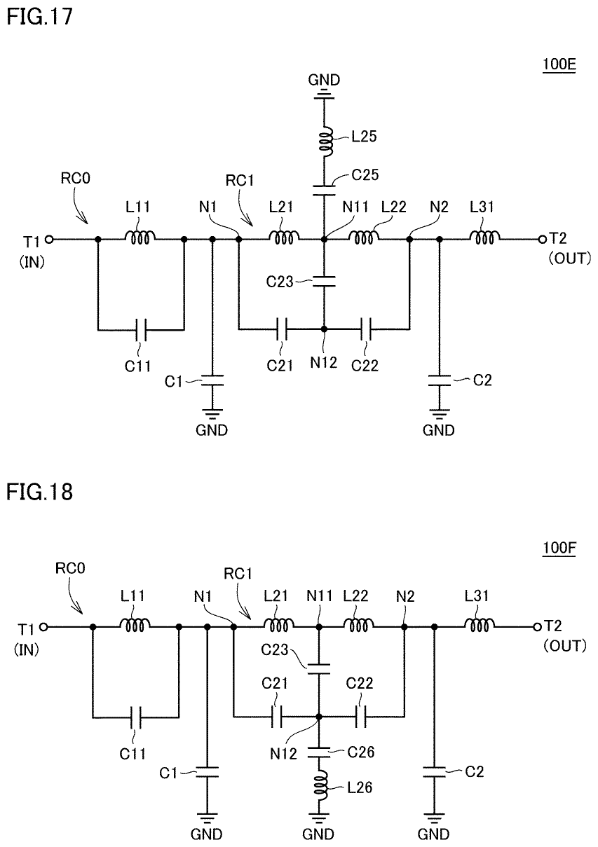

FIG. 17 is an equivalent circuit diagram of a filter device 100E according to a fourth modification. In the filter device 100E, an inductor L25 is added to the filter device 100C according to the second embodiment illustrated in FIG. 11. More specifically, the inductor L25 is disposed between the capacitor C25 and the ground terminal GND. An LC series resonator is constituted by the capacitor C25 and the inductor L25.

In this manner, the anti-resonant frequency and the resonant frequency of spurious can be brought closer by disposing an LC series resonator between the capacitor for adjusting the frequency of spurious and the ground terminal GND, which makes it possible to reduce the level of spurious through the cancellation of an anti-resonant point and a resonant point.

The connection of the inductor L25 and the capacitor C25 in the LC series resonator may be reversed.

### (Fifth Modification)

In a fifth modification, an LC series resonator is disposed at a portion of the shunt capacitor for adjusting the level of spurious in the configuration according to the third modification.

FIG. 18 is an equivalent circuit diagram of a filter device 100F according to a fifth modification. In the filter device 100F, an inductor L26 is added to the filter device 100D according to the third modification illustrated in FIG. 16. More specifically, the inductor L26 is disposed between the capacitor C26 and the ground terminal GND. An LC series resonator is constituted by the capacitor C26 and the inductor L26.

In this manner, the anti-resonant frequency and the resonant frequency of spurious can be brought closer by disposing an LC series resonator between the capacitor for adjusting the frequency of spurious and the ground terminal GND. Consequently, it is possible to reduce the level of spurious through the cancellation of an anti-resonant point and a resonant point.

The connection of the inductor L26 and the capacitor C26 in the LC series resonator may be reversed.

### Third Embodiment

In a third embodiment, the features of the present disclosure are applied to a seventh-order low pass filter.

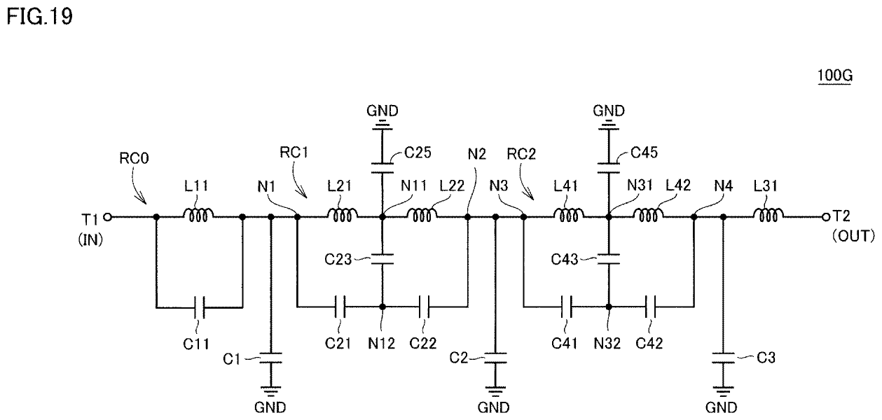

FIG. 19 is an equivalent circuit diagram of a filter device 100G according to a third embodiment. In the filter device 100G, a resonator RC2 configured similarly to the resonator RC1, a capacitor C45 for adjusting the level of spurious, and a shunt capacitor C3 are added to the filter device 100C according to the second embodiment illustrated in FIG. 11.

With reference to FIG. 19, in the filter device 100G, the resonator RC2 is connected between the terminal N2 of the resonator RC1 and the inductor L31. The resonator RC2 includes inductors L41 and L42 and capacitors C41 to C43.

In the resonator RC2, the inductors L41 and L42 connected in series are connected between a terminal N3 (third terminal) connected to the terminal N2 of the resonator RC1 and a terminal N4 (fourth terminal) connected to the inductor L31. One end of the capacitor C41 is connected to the terminal N3, and the other end thereof is connected to one end of the capacitor C42. The other end of the capacitor C42 is connected to the terminal N4. That is, the capacitors C41 and C42 connected in series are connected in parallel with the inductors L41 and L42 connected in series. The capacitor C43 for adjusting the frequency of spurious is connected between a connection node N31 between the inductor L41 and the inductor L42 and a connection node N32 between the capacitor C41 and the capacitor C42.

The capacitor C45 for adjusting the level of spurious is connected between the connection node N31 between the inductor L41 and the inductor L42 and the ground terminal GND. Further, the capacitor C3 is connected between the terminal N4 and the ground terminal GND.

With such a configuration, the filter device 100G constitutes a seventh-order low pass filter. With the capacitors C43 and C45, it is possible to reduce the frequency and the level of spurious generated by the inductors of the resonator RC2, which improves the attenuation characteristics of the low pass filter.

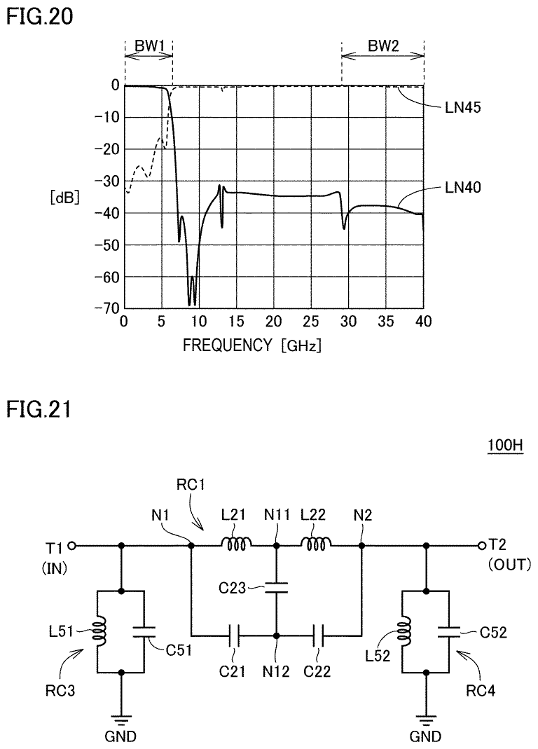

FIG. 20 illustrates filter characteristics of the filter device 100G according to the third embodiment. Also in FIG. 20, the horizontal axis indicates the frequency, and the vertical axis indicates the insertion loss (solid line LN40) and the return loss (broken line LN45). As indicated by the line LN40 in FIG. 20, spurious is generated around 13 GHz between the frequency band BW1 of microwaves and the frequency band BW2 of millimeter waves. Further, the attenuation characteristics in the non-pass band of 13 GHz or more are substantially flat with attenuation of 30 dB or more.

As described above, also in a seventh-order low pass filter, the frequency and the level of spurious to be generated can be adjusted by disposing a capacitor for frequency adjustment between an intermediate portion of the inductors and an intermediate portion of the capacitors of the LC parallel resonator and disposing a shunt capacitor for the capacitor for frequency adjustment, thereby preventing or reducing a deterioration in attenuation characteristics of the low pass filter.

Also in the filter device 100G, the portion of the capacitors C43 and C45 may be replaced with an LC series resonator as in FIG. 9. A capacitor or an LC series resonator may be disposed between the connection node N32 between the capacitor C41 and the capacitor C42 and the ground terminal GND, as in FIG. 16 or 18.

The “resonator RC2” according to the third embodiment corresponds to the “second resonator” according to the present disclosure. The “capacitor C3”, “capacitor C41”, “capacitor C42”, and “capacitor C43” according to the third embodiment correspond to the “eighth to eleventh capacitors”, respectively, according to the present disclosure. The “inductor L41” and “inductor L42” according to the third embodiment correspond to the “fifth inductor” and “sixth inductor”, respectively, according to the present disclosure.

### Fourth Embodiment

In the above embodiments and modifications, the filter device is a low pass filter. In a fourth embodiment, the features of the present disclosure are applied to a third-order or higher-order band pass filter in which an LC parallel resonator is used.

FIG. 21 is an equivalent circuit diagram of a filter device 100H according to a fourth embodiment. In the filter device 100H, the capacitors C1 and C2 in the filter device 100B as a third-order low pass filter illustrated in FIG. 10 have been replaced with resonators RC3 and RC4, respectively.

The resonator RC3 includes an inductor L51 and a capacitor C51 connected in parallel between the terminal N1 of the resonator RC1 and the ground terminal GND. The resonator RC4 includes an inductor L52 and a capacitor C52 connected in parallel between the terminal N2 of the resonator RC1 and the ground terminal GND. That is, the resonators RC3 and RC4 constitute an LC parallel resonator, and the filter device 100H functions as a third-order band pass filter.

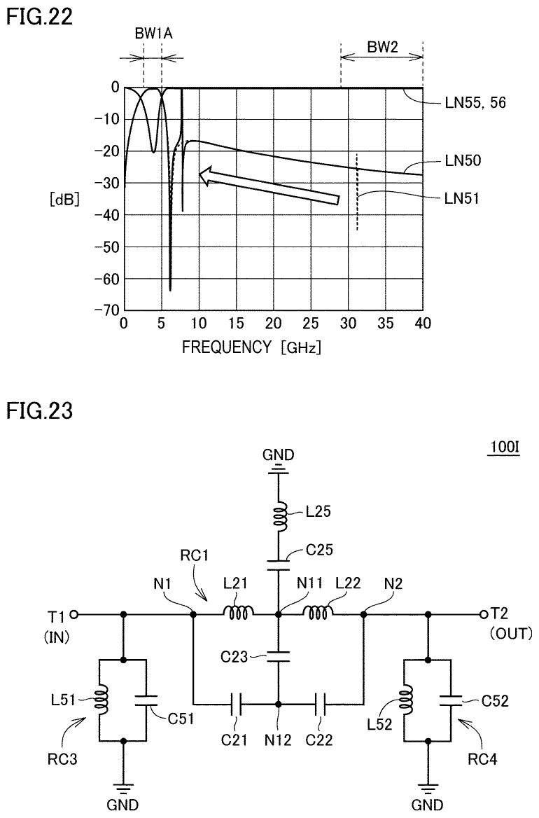

FIG. 22 illustrates filter characteristics of the filter device 100H according to the fourth embodiment. FIG. 22 indicates not only the insertion loss (solid line LN50) and the return loss (solid line LN55) for the filter device 100H, but also the insertion loss (broken line LN51) and the return loss (broken line LN56) for a comparative example in which the capacitor C23 has been removed from the configuration in FIG. 21.

As illustrated in FIG. 22, spurious generated around 31 GHz in the frequency band BW2 of millimeter waves in the configuration of the comparative example is moved to around 8 GHz in the filter device 100H. Consequently, the effect on the frequency band BW2 of millimeter waves is reduced.

As described above, also with a band pass filter, the frequency of spurious generated by the inductor of the resonator RC1 can be adjusted to a frequency that does not affect the pass band of another signal by the capacitor C23 included in the resonator RC1. Thus, a deterioration in attenuation characteristics of the band pass filter can be prevented or reduced.

The “resonator RC3” and “resonator RC4” according to the fourth embodiment correspond to the “third resonator” and “fourth resonator”, respectively, according to the present disclosure. The “inductor L51” and “inductor L52” according to the fourth embodiment correspond to the “seventh inductor” and “eighth inductor”, respectively, according to the present disclosure. The “capacitor C51” and “capacitor C52” according to the fourth embodiment correspond to the “twelfth capacitor” and “thirteenth capacitor”, respectively, according to the present disclosure.

### (Sixth Modification)

In a sixth modification, an LC series resonator for adjusting the level of spurious is further added to the filter device 100H according to the fourth embodiment.

FIG. 23 is an equivalent circuit diagram of a filter device 100I according to a sixth modification. In the filter device 100I, as in the fourth modification illustrated in FIG. 17, an LC series resonator constituted by the inductor L25 and the capacitor C25 is disposed between the first connection node N11 between the inductor L21 and the inductor L22 in the resonator RC1 and the ground terminal GND. With such a configuration, it is possible to adjust the frequency at which spurious is to be generated, and reduce the level of spurious to be generated.

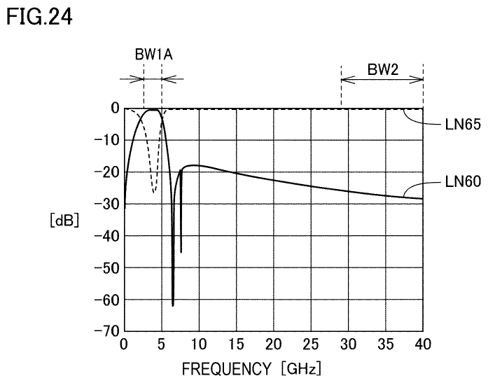

FIG. 24 illustrates filter characteristics of the filter device 100I according to the sixth modification. FIG. 24 indicates the insertion loss (solid line LN60) and the return loss (broken line LN65) for the filter device 100I.

With reference to FIG. 22 together with FIG. 24, it can be seen that the level of spurious generated around 8 GHz is reduced for the filter device 100I by ten and several decibels compared to the case in FIG. 22.

In this manner, also with a band pass filter, the frequency and the level of spurious generated by the inductor included in the filter device can be adjusted by connecting a shunt capacitor to the capacitor for adjusting the frequency of spurious.

### [Aspects]

A person skilled in the art will understand that the plurality of exemplary embodiments discussed above are specific examples of the following aspects.

(1) An aspect provides a filter device including an input terminal, an output terminal, and a first resonator connected to the input terminal and the output terminal. The first resonator includes a first terminal connected to the input terminal, a second terminal connected to the output terminal, first and second inductors, and first to third capacitors. One end of the first inductor is connected to the first terminal. One end of the second inductor is connected to the second terminal, and the other end thereof is connected to the other end of the first inductor. One end of the first capacitor is connected to the first terminal. One end of the second capacitor is connected to the second terminal, and the other end thereof is connected to the other end of the first capacitor. The third capacitor is connected between the other end of the first inductor and the other end of the first capacitor.

(2) The filter device according to (1), further including a fourth capacitor connected between the third capacitor and the ground terminal.

(3) The filter device according to (2), in which the fourth capacitor is connected between the other end of the first inductor and the ground terminal.

(4) The filter device according to (2), in which the fourth capacitor is connected between the other end of the first capacitor and the ground terminal.

(5) The filter device according to any one of (1) to (4), further including a ground terminal, a fifth capacitor connected between the first terminal and the ground terminal, and a sixth capacitor connected between the second terminal and the ground terminal.

(6) The filter device according to (5), in which the filter device uses a first frequency band as a pass band, and uses, as a non-pass band, a frequency band that is higher than the first frequency band. The third capacitor generates spurious in a frequency band between a second frequency band included in the non-pass band and the first frequency band.

(7) The filter device according to (5), further including a third inductor connected between the input terminal and the first terminal, a seventh capacitor connected in parallel with the third inductor, and a fourth inductor connected between the output terminal and the second terminal.

(8) The filter device according to (7), further including a second resonator connected between the second terminal and the fourth inductor, and an eighth capacitor connected between a connection node between the second resonator and the fourth inductor and the ground terminal. The second resonator includes a third terminal connected to the second terminal, a fourth terminal connected to the fourth inductor, fifth and sixth inductors, and ninth to eleventh capacitors. One end of the fifth inductor is connected to the third terminal. One end of the sixth inductor is connected to the fourth inductor, and the other end thereof is connected to the other end of the fifth inductor. One end of the ninth capacitor is connected to the third terminal. One end of the tenth capacitor is connected to the fourth inductor, and the other end thereof is connected to the other end of the fifth capacitor. The eleventh capacitor is connected between the other end of the fifth inductor and the other end of the ninth capacitor.

(9) The filter device according to any one of (1) to (4), further including a ground terminal, a third resonator connected between the first terminal and the ground terminal, and a fourth resonator connected between the second terminal and the ground terminal. The third resonator includes a seventh inductor connected between the first terminal and the ground terminal, and a twelfth capacitor connected in parallel with the seventh inductor. The fourth resonator includes an eighth inductor connected between the second terminal and the ground terminal, and a thirteenth capacitor connected in parallel with the eighth inductor.

(10) An aspect provides a filter device including a multilayer body in which a plurality of dielectrics are stacked, an input terminal, an output terminal, a ground terminal, first and second paths, and first to fourth capacitor electrodes. The first path is connected to the input terminal. The second path is connected to the output terminal. The first capacitor electrode is connected to the first path. The second capacitor electrode is connected to the second path. The third capacitor electrode is connected to the first and second paths. When viewed in plan view from a stacking direction of the multilayer body, at least a part of the first capacitor electrode, at least a part of the second capacitor electrode, and at least a part of the third capacitor electrode are superposed on the fourth capacitor electrode.

(11) The filter device according to (10), in which the first capacitor electrode and the second capacitor electrode are disposed in an identical dielectric layer. The fourth capacitor electrode is disposed in a dielectric layer between the dielectric layer in which the first capacitor electrode and the second capacitor electrode are disposed and a dielectric layer in which the third capacitor electrode is disposed.

(12) The filter device according to (10) or (11), further including a ground electrode connected to the ground terminal, and a fifth capacitor electrode and a sixth capacitor electrode that are connected to the third capacitor electrode. When viewed in plan view from the stacking direction of the multilayer body, at least a part of the fifth capacitor electrode and at least a part of the sixth capacitor electrode are superposed on the ground electrode.

The embodiments disclosed herein should be construed as illustrative in all respects and not restrictive. The scope of the present invention is defined not by the description of the above embodiments but by the claims, and is intended to encompass all changes that fall within the meaning and scope of the claims and equivalents thereof.

### REFERENCE SIGNS LIST

100, 100A to 100I, 100X filter device, 110 multilayer body, 111 upper surface, 112 lower surface, C1 to C3, C11, C21 to C23, C21X, C25, C26, C41 to C43, C45, C51, C52, Cb capacitor, DM direction mark, GND ground terminal, L11, L21 to L23, L25, L26, L21X, L31, L41, L42, L51, L52 inductor, LY1 to LY14 dielectric layer, N1 to N4 terminal, N11, N12, N31, N32 connection node, P1, P4, PL10, PL11, PL20, PL30 to PL32 flat plate electrode, PC1 to PC4, PC10 to PC12, PC20 to PC26 capacitor electrode, PG1 ground electrode, RC0 to RC4, RC1X resonator, T1 input terminal, T2 output terminal, V10 to V14, V20 to V23, V20C, V21C, V31, V32, V40, V41, VG1 via

1. A filter device comprising:
an input terminal, an output terminal, and a ground terminal; and
a first resonator connected to the input terminal and the output terminal,
wherein the first resonator includes
a first terminal connected to the input terminal,
a second terminal connected to the output terminal,
a first inductor having a first end connected to the first terminal,
a second inductor having a first end connected to the second terminal and a second end connected to a second end of the first inductor,
a first capacitor having a first end connected to the first terminal,
a second capacitor having a first end connected to the second terminal and a second end connected to a second end of the first capacitor, and
a third capacitor connected between the second end of the first inductor and the second end of the first capacitor.

2. The filter device according to claim 1, further comprising a fourth capacitor connected between the third capacitor and the ground terminal.

3. The filter device according to claim 2, wherein the fourth capacitor is connected between the second end of the first inductor and the ground terminal.

4. The filter device according to claim 3, further comprising a fifth inductor connected in series with the fourth capacitor, wherein the fourth capacitor and the fifth inductor form a series resonator connected between the other end of the first inductor and the ground terminal.

5. The filter device according to claim 2, wherein the fourth capacitor is connected between the second end of the first capacitor and the ground terminal.

6. The filter device according to claim 4, further comprising a fifth inductor connected in series with the fourth capacitor, wherein the fourth capacitor and the fifth inductor form a series resonator connected between the other end of the first inductor and the ground terminal.

7. The filter device according to claim 1, further comprising
a fifth capacitor connected between the first terminal and the ground terminal, and
a sixth capacitor connected between the second terminal and the ground terminal.

8. The filter device according to claim 7,
wherein the filter defines a pass band in a first frequency and a non-pass band in a frequency range higher than the first frequency band, and
the third capacitor generates spurious in a frequency band between a second frequency band within the non-pass band and the first frequency band.

9. The filter device according to claim 7, further comprising
a third inductor connected between the input terminal and the first terminal,
a seventh capacitor connected in parallel with the third inductor, and
a fourth inductor connected between the output terminal and the second terminal.

10. The filter device according to claim 9, further comprising
a second resonator connected between the second terminal and the fourth inductor, and
an eighth capacitor connected between a connection node between the second resonator and the fourth inductor and the ground terminal,
wherein the second resonator includes
a third terminal connected to the second terminal,
a fourth terminal connected to the fourth inductor,
a fifth inductor a first end connected to the third terminal,
a sixth inductor having a first end connected to the fourth inductor and a second end of which is connected to the a second end of the fifth inductor,
a ninth capacitor having a first end connected to the third terminal,
a tenth capacitor having a first end connected to the fourth inductor and a second end connected to a second end of the ninth capacitor, and
an eleventh capacitor connected between a second end of the fifth inductor and a second end of the ninth capacitor.

11. The filter device according to claim 1, further comprising
a third resonator connected between the first terminal and the ground terminal, and
a fourth resonator connected between the second terminal and the ground terminal,
wherein the third resonator includes
a seventh inductor connected between the first terminal and the ground terminal, and
a twelfth capacitor connected in parallel with the seventh inductor, and
the fourth resonator includes
an eighth inductor connected between the second terminal and the ground terminal, and
a thirteenth capacitor connected in parallel with the eighth inductor.

12. The filter device according to claim 1, further comprising a third inductor connected in series with the third capacitor between the first connection node and the second connection node.

13. The filter device according to claim 1, wherein the first inductor and the second inductor have substantially equal inductance values.

14. A filter device comprising:
a multilayer body in which a plurality of dielectrics are stacked;
an input terminal, an output terminal, and a ground terminal disposed in the multilayer body;
a first path connected to the input terminal;
a second path connected to the output terminal;
a first capacitor electrode connected to the first path;
a second capacitor electrode connected to the second path;
a third capacitor electrode connected in series between the first path and the second path; and
a fourth capacitor electrode,
wherein when viewed in plan view from a stacking direction of the multilayer body, at least a part of the first capacitor electrode, at least a part of the second capacitor electrode, and at least a part of the third capacitor electrode are superposed on the fourth capacitor electrode.

15. The filter device according to claim 14,
wherein the first capacitor electrode and the second capacitor electrode are in a first dielectric layer, and
the fourth capacitor electrode is in a second dielectric layer between the first dielectric layer and a third dielectric layer in which the third capacitor electrode is disposed.

16. The filter device according to claim 14, further comprising
a ground electrode connected to the ground terminal, and
a fifth capacitor electrode and a sixth capacitor electrode that are connected to the third capacitor electrode,
wherein when viewed in plan view from the stacking direction of the multilayer body, at least a part of the fifth capacitor electrode and at least a part of the sixth capacitor electrode are superposed on the ground electrode.

17. A method for controlling spurious signals in a filter device having a pass band and a non-pass band, the filter device including an LC parallel resonator having a series inductor path and a series capacitor path, the method comprising:
splitting the series inductor path into a first inductor and a second inductor joined at a first node;
splitting the series capacitor path into a first capacitor and a second capacitor joined at a second node; and
connecting a third capacitor between the first node and the second node, wherein a capacitance of the third capacitor is selected to shift a frequency of a spurious signal generated by the LC parallel resonator to a frequency range outside of a predetermined operational band within the non-pass band.
